(19) United States
(12) Patent Application Publication
(10) Pub. No.: US 2009/0230395 A1
(43) Pub. Date: Sep. 17, 2009

(54) THIN FILM TRANSISTOR SUBSTRATE AND METHOD FOR MANUFACTURING THE SAME

(76) Inventors: Jin-Suk Lee, Gwangmyeong-si (KR); Jin-Goo Jung, Seongnam-si (KR)

Correspondence Address: Haynes and Boone, LLP;IP Section, 2323 Victory Avenue, SUITE 700, Dallas, TX, 75219, US

(21) Appl. No.: 12/272,557

(22) Filed: Nov. 17, 2008

(30) Foreign Application Priority Data
Mar. 17, 2008 (KR) 10-2008-0024465

(51) Int. Cl. H01L 29/04; H01L 21/336

(52) U.S. Cl. 257/59; 438/160; 257/E29.003; 257/E21.414

(57) ABSTRACT

A thin film transistor substrate and a method for manufacturing the same are provided. The thin film transistor substrate has a display area and a pad area defined in the vicinity of the display area, and includes a signal line formed in the display area and a signal pad formed in the pad area, and at least one connecting line which connects the signal line and the signal pad and includes a first line and a second line disposed on the first line. In addition, at least one of the first line and the second line has centrally isolated, spaced apart stepped structures.

### CROSS-REFERENCE TO RELATED APPLICATION

This application claims priority from Korean Patent Application No. 10-2008-0024465 filed on Mar. 17, 2008 in the Korean Intellectual Property Office, the disclosure of which is incorporated herein by reference in its entirety.

### BACKGROUND OF THE INVENTION

1. Field of the Invention

The present invention relates to a thin film transistor substrate and a method for manufacturing the same, and more particularly, to a thin film transistor substrate which can prevent exposure of lines existing in a dual exposure area during patterning of a protection layer, and a method for manufacturing the same.

2. Description of the Related Art

Liquid crystal displays capable of displaying images by controlling transmittance of light incident from a light source using optical anisotropy of liquid crystals and polarizing properties of a polarizing plate, have some notable advantages, such as lightness, thin profile, compact size, superior resolution, large screen size, and low power consumption, and have recently been used in a wide variety of applications.

A method of the liquid crystal display generally includes forming a thin film on a substrate to a predetermined thickness, depositing a photoresist on the thin film formed on the substrate in a desired pattern, etching the resultant product, repeatedly performing the depositing the photoresist and the etching to sequentially form a desired thin film pattern on the substrate. In the depositing of the photoresist, a photoresist film is coated on the substrate having the thin film formed thereon, and the photoresist film is exposed using an exposure mask having a predetermined pattern. Here, the predetermined pattern formed on the exposure mask is transferred to the photoresist film, so that a portion of the predetermined pattern is removed in a subsequent development process and the other portion of the predetermined pattern remains unremoved, thereby forming a photoresist film pattern corresponding to the predetermined pattern of the exposure mask. Then, the thin film disposed under the photoresist film pattern is etched using a mask, thereby forming a desired thin film pattern.

Recently, as a screen size of an LCD has gradually been increasing, it is quite difficult to accomplish exposure on the overall area of the substrate of the LCD at a time. Accordingly, the overall substrate of the LCD is divided into a plurality of exposure areas to then be subjected to divisional exposure using a plurality of shots. Here, the divisional exposure may be carried out on an independently operable cell unit at a time, which is called a “shot”. Alternatively, the divisional exposure may be carried out repeatedly on a plurality of divided cells, which are called “stitch shots”. During the divisional exposure, various processing parameters, such as an exposure margin, should be taken into consideration. In this regard, the substrate is divided into the respective unit exposure areas so as to overlap partially each other at their boundary portions.

However, in an overlapping exposure area, a protection layer having photosensitivity for protecting lines may be removed in an etching process due to dual exposure, so that the lines may partially be exposed to the outside. The exposed lines may be covered and protected by another protection layer formed in a subsequent process but some of the exposed lines may still be exposed to the air, resulting in wiring corrosion over time. As such, the conventional liquid crystal display renders several problems, including wiring corrosion due to exposure of some lines, or malfunction caused by short-circuit or open-circuit due to wiring corrosion occurring after extended period of time.

### SUMMARY OF THE INVENTION

The present invention provides a thin film transistor substrate and a manufacturing method thereof, which can prevent at least some of lines from remaining after dual exposure and being exposed in a structure in which the lines are formed on a substrate covered by a protection layer, by relatively thickly forming the protection layer formed thereat to provide stepped structures located over or below some of the lines.

The present invention also provides a thin film transistor substrate and a manufacturing method thereof, which can provide a high initial operation reliability even after prolonged use, by eliminating causes of malfunction occurring after extended period of time, such as short-circuit or open-circuit due to wiring corrosion, that is, by preventing wiring corrosion due to wiring exposure.

The above and other objects of the present invention will be described in or be apparent from the following description of the preferred embodiments.

According to an aspect of the present invention, there is provided a thin film transistor substrate including a substrate having a display area and a pad area defined in the vicinity of the display area, the thin film transistor substrate including a signal line formed in the display area and a signal pad formed in the pad area, and at least one connecting line which connects the signal line and the signal pad and includes a first line and a second line disposed on the first line, wherein at least one of the first line and the second line has centrally isolated, spaced apart stepped structures.

The signal line may include a gate line and a data line.

The first line may be made of the same material as the gate line, and the second line may be made of the same material as the data line.

A protection layer may be formed over the signal line and the signal pad.

The protection layer may include at least one contact hole, and the centrally isolated, spaced apart stepped structures may correspond to a dual exposure area during an exposure process for forming the contact hole.

A distance between the stepped structures may be greater than or equal to a width of the dual exposure area.

The distance between the stepped structures may be in a range of about 1 to 5 μm, and a step height may be in a range of about 0.5 to 1.0 μm.

According to another aspect of the present invention, there is provided a method for manufacturing the thin film transistor substrate including providing a substrate, forming a first conductive film on the substrate, patterning the first conductive film to form a gate line, a gate pad and a gate connecting line which connects the gate line and the gate pad, forming an insulating layer on the overall structure which includes the gate line, the gate pad and the gate connecting line, and forming a second conductive film on the overall structure which includes the gate line, the gate pad and the gate connecting line, and patterning the second conductive film to form a data line, a data pad and a data connecting line which connects the data line and the data pad, wherein the patterning of the second conductive film comprises forming centrally isolated, spaced apart stepped structures on a portion of the gate connecting line using a portion of the second conductive film.

The patterning of the second conductive film may further comprise forming a protection layer on the data pattern, and partially removing the protection layer to form a contact hole.

The forming of the contact hole may comprise forming a photoresist layer on the protection layer by carrying out divisional exposure on the photoresist layer to form a photoresist layer pattern, and etching the protection layer using the photoresist layer pattern as an etch mask.

The divisional exposure may be carried out by partially overlapping the exposure area in a state in which the exposure area subjected to dual exposure due to overlapping is equal to or smaller than a distance between the stepped structures.

An overlapping margin of the divisional exposure may be in a range of about 1 to 2 μm.

The distance between the stepped structures may be in a range of about 1 to 5 μm, and a step height is in a range of about 0.5 to 1.0 μm.

According to still another aspect of the present invention, there is provided a method for manufacturing the thin film transistor substrate including providing a substrate, forming a first conductive film on the substrate, patterning the first conductive film to form a gate line, a gate pad and a gate connecting line which connects the gate line and the gate pad, forming an insulating layer on the overall structure which includes the gate line, the gate pad and the gate connecting line, and forming a second conductive film on the overall structure including the gate line, the gate pad and the gate connecting line, and patterning the second conductive film to form a data line, a data pad and a data connecting line which connects the data line and the data pad, wherein the patterning of the first conductive film comprises forming centrally isolated, spaced apart stepped structures on a portion of the data connecting line using a portion of the first conductive film.

After the patterning of the second conductive film, the method may further include forming a protection layer on the data pattern, and partially removing the protection layer to form a contact hole.

The forming of the contact hole may comprise forming a photoresist layer on the protection layer by carrying out divisional exposure on the photoresist layer to form a photoresist layer pattern, and etching the protection layer using the photoresist layer pattern as an etch mask.

The divisional exposure may be carried out by partially overlapping the exposure area in a state in which the exposure area subjected to dual exposure due to overlapping is equal to or smaller than the distance between the stepped structures.

An overlapping margin of the divisional exposure may be in a range of about 1 to 2 μm.

The distance between the stepped structures may be in a range of about 1 to 5 μm, and a step height may be in a range of about 0.5 to 1.0 μm.

### BRIEF DESCRIPTION OF THE DRAWINGS

The above and other features and advantages of the present invention will become more apparent by describing in detail preferred embodiments thereof with reference to the attached drawings in which:

FIG. 1 is a plan view of a thin film transistor substrate according to a first embodiment of the present invention;

FIG. 2 is a sectional view of the thin film transistor substrate shown in FIG. 1;

FIGS. 3 through 7 are sectional views illustrating a portion of a display area for explaining a method for manufacturing the thin film transistor substrate shown in FIG. 1;

FIGS. 8 through 12 are sectional views illustrating a portion of a pad area for explaining a method for manufacturing the thin film transistor substrate shown in FIG. 1;

FIG. 13 is a plan view of a thin film transistor substrate according to a second embodiment of the present invention;

FIG. 14 is a sectional view of the thin film transistor substrate shown in FIG. 13; and

FIGS. 15 through 19 are sectional views illustrating a portion of a pad area for explaining a method for manufacturing the thin film transistor substrate shown in FIG. 13.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Hereinafter, the present invention will be explained in more detail with reference to the accompanying drawings.

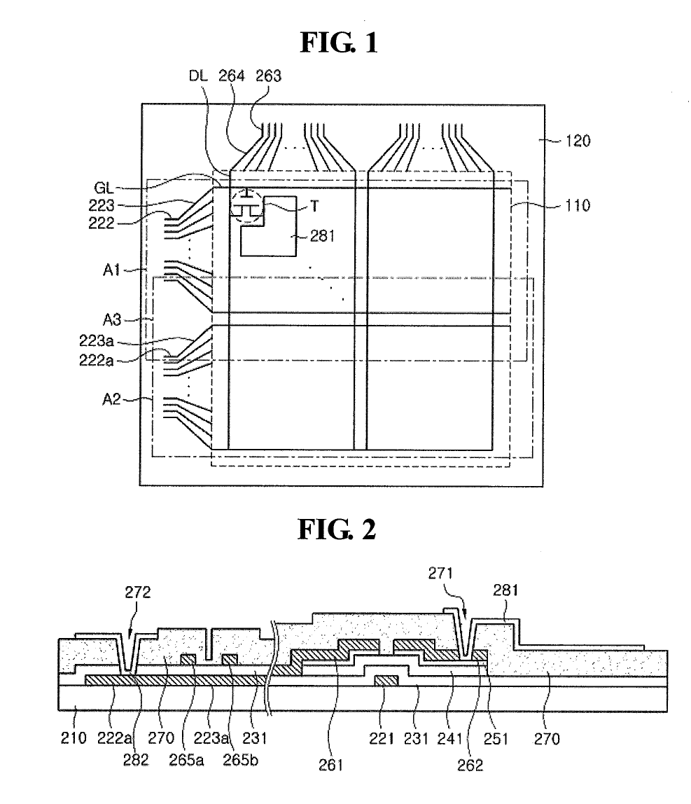

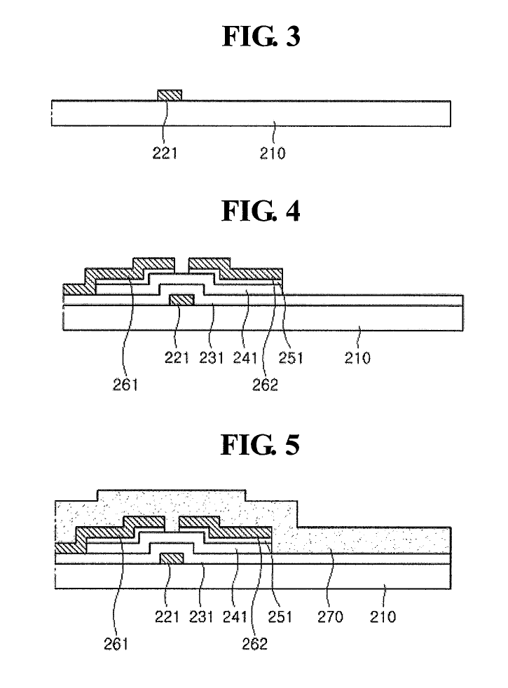

FIG. 1 is a plan view of a thin film transistor substrate according to a first embodiment of the present invention, and FIG. 2 is a sectional view of the thin film transistor substrate shown in FIG. 1.

Referring to FIGS. 1 and 2, the thin film transistor substrate includes a display area 110 in which pixels for forming an image are formed, and a pad area 120 which is formed exterior to the display area 110 and in which pads 222 and 263 for applying image signals to the pixels are formed. In addition, the thin film transistor substrate includes a transparent insulating substrate 210, a gate line GL extending on the substrate 210 in one direction, and a data line (DL) extending on the substrate 210 in a direction perpendicular to the gate line GL. Here, a pixel is defined at a crossing area of the gate line GL and the data line DL or adjacent areas thereof. Each pixel has a thin film transistor T, and a pixel electrode 281. A storage electrode (not shown) may further be formed.

The thin film transistor T includes a gate electrode 221, an insulating layer 231, an active layer 241, an ohmic contact layer 251, a source electrode 261, and a drain electrode 262. Here, the gate electrode 221 is connected to the gate line GL, the source electrode 261 is connected to the data line DL, and the drain electrode 262 is connected to the pixel electrode 281 through a first contact hole 271. Thus, when a predetermined gate signal is applied to the gate electrode 221 through the gate line GL, a conduction channel is formed in the active layer 241, so that the data signal transmitted through the data line DL is applied to the pixel electrode 281. The storage electrode (not shown) constitutes a storage capacitor together with the pixel electrode 281 formed thereon, and is connected to a storage line (not shown) substantially in parallel with the gate line GL to be supplied with a reference voltage. Accordingly, the data signal can be stored in a stable manner through the storage capacitor until the data signal charged in the pixel electrode 281 is replenished. In order to achieve electric insulation, an insulating layer 231 is formed between the gate line GL and the data line DL, and a protection layer 270 is formed between the data line DL and the pixel electrode 281.

Meanwhile, the gate line GL and the data line DL extend outside with respect to the display area 110 and is electrically connected to the gate pad 222 and the data pad 263 formed in the pad area 120. Here, the gate line GL and the data line DL distributed in a relatively wide area are connected to the gate pad 222 and the data pad 263 formed in a relatively narrow area via a fan-out area in which a gap between adjacent lines gradually decreases. In the following description, a line formed in the fan-out area and connecting the gate line GL and the gate pad 222 is denoted as the gate connecting line 223, a line which connects the data line DL and data pad 263 is denoted as the data connecting line 264.

The gate connecting line 223 is plurally formed and is made of the same material as the data line DL, including one or more gate connecting lines 223a having centrally isolated, spaced apart stepped structures 265a and 265b. The width of an isolation area of the stepped structures 265a and 265b is much smaller than the thickness of a layer to be formed in a subsequent step, that is, the protection layer 270. Accordingly, when the thicker protection layer 270 formed on the stepped structures 265a and 265b is planarized, the protection layer 270 formed on the isolation area, as the result of planarizing of the stepped structures 265a and 265b, may be formed about a thickness corresponding to a step height more thickly than the protection layer 270 formed on a non-isolation area. Here, the thick protection layer 270 has photosensitivity and protects a given area to be subjected to dual exposure from being completely removed in a patterning step of the protection layer 270. Even if a subsequent layer is not formed in the given area, the thick protection layer 270 can prevent the gate connecting lines 223a from being exposed to the outside. As a result, it is possible to prevent the gate connecting lines 223a from corroding due to exposure. Meanwhile, the gate connecting lines 223a are preferably provided at an area where exposure is duplicated during the patterning of the protection layer 270 overlying the gate connecting lines 223a, that is, a dual exposure area. More preferably, the isolation area of the stepped structures 265a and 265b is provided corresponding to the dual exposure area. Here, a distance of the stepped structures 265a and 265b is preferably equal to or greater than a width of the dual exposure area. For example, if the distance of the stepped structures 265a and 265b is less than 1 μm, it is quite difficult to perform patterning. In a case where the distance of the stepped structures 265a and 265b is greater than 5 μm, if the protection layer has a thickness of 4 μm or less, the central isolation area may not be completely filled but an unfilled portion thereof may remain. Thus, the distance of the stepped structures 265a and 265b is preferably in a range of about 1 to about 5 μm. In addition, since the protection layer 270 is etched to a thickness of about 0.4 to about 0.7 μm when patterning is performed to form the contact hole, the stepped structures 265a and 265b preferably has a step height in a range of about 0.5 to about 1.0 μm.

A method for manufacturing the aforementioned thin film transistor substrate according to the first embodiment of the present invention will now be described. The following explanation will be made separately with regard to a display area 110 and a pad area 120.

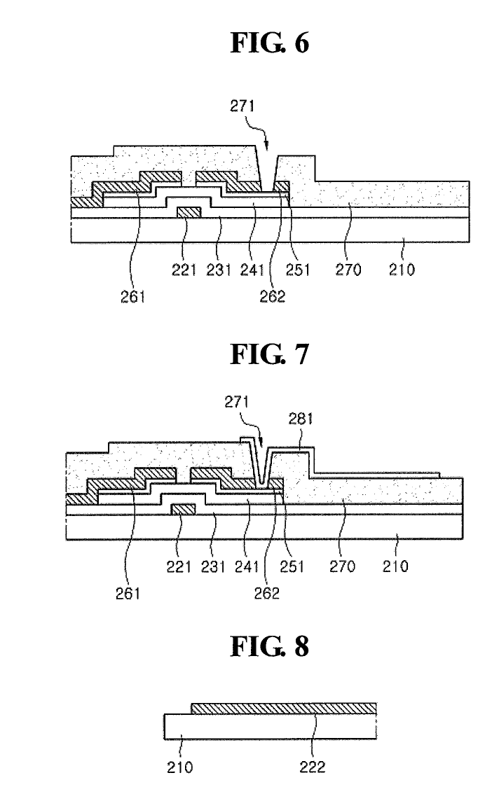

FIGS. 3 through 7 are sectional views illustrating a portion of a display area for explaining a method for manufacturing the thin film transistor substrate shown in FIG. 1.

Referring to FIG. 3, a transparent insulating substrate 210, e.g., glass substrate or quartz substrate, is provided, and a first conductive film is then formed on the substrate 210, followed by patterning, thereby forming the gate electrode 221 and the gate line GL. Here, the gate electrode 221 and the gate line GL are formed on the display area 110, and one end of the gate line GL partially extends toward the pad area 120 in the display area 110.

Meanwhile, in step of forming the gate line GL, the storage electrode and the storage line connected thereto may be formed at the same time. The first conductive film may have a structure of a single layer or multiple layers including at least one of Al, Mo, Cr, Ti, Ta, Ag, Ni, W and Nd.

Referring to FIG. 4, the insulating layer 231 is formed on the overall structure having the gate electrode 221 and the gate line GL, the active layer 241 and the ohmic contact layer 251 are then sequentially deposited on the resultant structure to form a multi-layered semiconductor structure, followed by patterning, thereby forming a semiconductor layer shaped of an isolated island over the gate electrode 221. Here, an inorganic material including at least one of silicon oxide (SiO₂) and silicon nitride (SiNx) having excellent adhering and insulating properties, is used as the insulating layer 231. Amorphous silicon (a-Si) may be used as the active layer 241. The active layer 241 may also be formed of polysilicon. The ohmic contact layer 251 may be made of silicide or n+ hydrogenated a-Si heavily doped with n-type impurity. Also the ohmic contact layer may be substituted with a highly doped polycrystalline silicon. In addition, the semiconductor layer shaped in an isolated island preferably includes one or more semiconductor islands in a pixel area. In a subsequent process, a second conductive film is formed on an overall structure including the island shaped semiconductor layer and then patterned, thereby forming the source electrode 261, the drain electrode 262, and the data line DL. Here, the second conductive film may have a structure of a single layer or multiple layers including at least one of Al, Mo, Cr, Ti, Ta, Ag, Ni, W and Nd. Next, the ohmic contact layer 251, exposed between the source electrode 261 and the drain electrode 262, is removed. As a result, at least one thin film transistor T including the gate electrode 221, the insulating layer 231, the active layer 241, the ohmic contact layer 251, the source electrode 261, and the drain electrode 262 is formed in the pixel area. The resultant thin film transistor T is used as a switching device independently controlling each pixel.

Referring to FIG. 5, a protection layer 270 is formed on the overall structure including the thin film transistor T. Here, the protection layer 270 may have a structure of a single layer or multiple layers including at least one of an inorganic insulating layer and an organic insulating layer. The protection layer according to this embodiment is formed by depositing an organic insulating layer, such as BCB (Benzene Cyclo Butane), SOG (Siloxane Polymer), or polyimide resin, on an inorganic insulating layer having excellent adhering and insulating properties, such as silicon oxide (SiO₂) and silicon nitride (SiNx). In this way, use of a low dielectric organic insulating layer as a thick layer reduces parasitic capacitance between a signal line, i.e., the gate line (GL) and/or the data line (DL) and the pixel electrode 281, so that the signal line, i.e., the gate line (GL) and/or the data line (DL) and the pixel electrode 281, overlap each other by a portion, thereby enhancing an aperture ratio.

Referring to FIG. 6, the protection layer 270 is patterned through a photolithography processes or an etching process to form the first contact hole 271 exposing a portion of the drain electrode 262. That is to say, after forming a photoresist layer on the protection layer 270, a photoresist layer pattern is formed by performing the photolithography processes including an exposure process and a developing process, the protection layer 270 is etched using the photoresist layer pattern as an etch mask to form the first contact hole 271.

Referring to FIG. 7, the first contact hole 271 is formed on the overall structure including the third conductive layer (not shown) and patterned to form the pixel electrode 281. Here, a pixel electrode 281 is electrically connected to a drain electrode 262 through a contact hole 271, a third conductive layer may be a transparent conductive layer made of, e.g., ITO (Indium Tin Oxide) or IZO (Indium Zinc Oxide).

Meanwhile, according to the current trend of a large screen size LCD, the thin film transistor substrate according to this embodiment is advantageously manufactured by carrying out divisional exposure divisional exposure because existing exposure equipment used to manufacture medium- and small-sized substrates can be utilized. In other words, as shown in FIG. 1, an overall area of the substrate is divided into a plurality of exposure areas A1 and A2 having the same pattern and the same area. Then, first exposure is carried out on a first exposure area A1 and an exposure mask is shifted to a second exposure area A2 to carry out second exposure. In such a manner, exposure is sequentially performed on the exposure areas A1 and A2. Here, in order to ensure a predetermined exposure margin, the plurality of exposure areas A1 and A2 are preferably configured to overlap each other at their boundaries by a predetermined portion A3. For example, according to this embodiment, the overlapping margin of the exposure area is set to be in a range of 1 to 2 μm. As such, since an overlapping area corresponding to the exposure area A3 is created during divisional exposure, dual exposure can be carried out. Here, some gate connecting lines 223a among lines provided in the pad area 120 may be exposed. Like in the current embodiment, if the centrally isolated, spaced apart stepped structures are formed on the gate connecting lines 223a in the dual exposure area, the protection layer 270 formed in the subsequent step is formed thickly, thereby preventing wiring exposure. It is to be noted that the dual exposure area A3 is exaggerated in FIG. 1 in order to show some gate connecting lines 223a existing in the dual exposure area A3. Hereinafter, a method for manufacturing the thin film transistor substrate which can prevent wiring exposure due to dual exposure will be described in more detail.

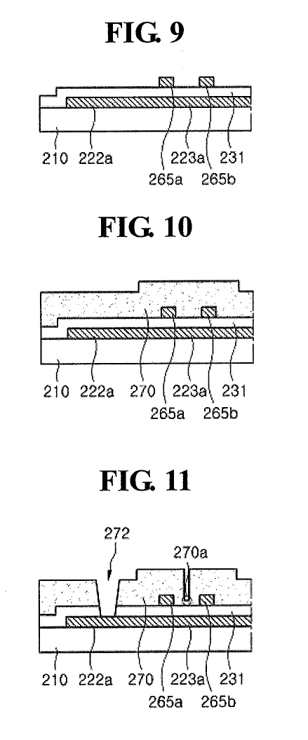

FIGS. 8 through 12 are sectional views illustrating a portion of a pad area for explaining a method for manufacturing the thin film transistor substrate shown in FIG. 1, which correspond to FIGS. 3 through 7, respectively.

Referring to FIGS. 1 and 8, in step of forming the gate line GL, the gate pad 222 and the gate connecting line 223 are formed in the pad area 120 of the substrate 210 using the first conductive film. Accordingly, the gate line GL formed in the display area 110 of the substrate 210 is connected to the gate pad 222 through the gate connecting line 223 to then receive gate signals through the gate pad 222.

Referring to FIGS. 1 and 9, in step of forming the data line DL, the data pad 263 and the data connecting line 264 are formed in the pad area 120 of the substrate 210 using the second conductive film. Accordingly, the data line DL formed in the display area 110 of the substrate 210 is connected to the gate pad 222 through the data connecting line 264 to then receive data signals through the data pad 263.

Meanwhile, centrally isolated, spaced apart stepped structures 265a and 265b are formed on the insulating layer 231 over the gate connecting lines 223a existing in the dual exposure area A3 when patterning of the protection layer 270 using a portion of the second conductive film. Here, the isolation area of the stepped structures 265a and 265b may be formed by removing partially or completely the second conductive film. In addition, the isolation area of the stepped structures 265a and 265b is preferably equal to or greater than a width of the dual exposure area A3 during patterning of the protection layer 270.

Referring to FIGS. 1 and 10, in step of forming the protection layer 270, the protection layer 270 is formed over the entire pad area 120 including the stepped structures 265a and 265b. Here, the protection layer 270 is preferably much thicker than a distance between the stepped structures 265a and 265b.

Accordingly, the protection layer 270 formed on the isolation area as the result of planarizing of the stepped structures 265a and 265b may be formed about a thickness corresponding to a step height more thickly than the protection layer formed on a non-isolation area.

Referring to FIGS. 1 and 11, in step of patterning the protection layer 270, the protection layer 270 formed in the pad area 120 of the substrate 210 is patterned to form a second contact hole 272. That is to say, after forming a photoresist layer on the protection layer 270, a photoresist layer pattern is formed by performing a photolithography processes including an exposure process and a developing process, the protection layer 270 is etched using the photoresist layer pattern as an etch mask to form the second contact hole 272. During the exposure process, an overall area of the substrate 210 may be divided into a plurality of exposure areas A1 and A2 to carry out divisional exposure. Here, in order to ensure a predetermined exposure margin, the plurality of exposure areas A1 and A2 may be configured to overlap each other at their boundaries by a predetermined portion A3. In the general etching process, since the protection layer 270 is completely removed through dual exposure, some gate connecting lines 223a existing in a pertinent area may be exposed. However, during the etching process according to this embodiment, the centrally isolated, spaced apart stepped structures 265a and 265b are formed on the gate connecting line 223 existing in the dual exposure area A3. Accordingly, on the isolation area of the stepped structures 265a and 265b corresponding to the dual exposure area A3, the protection layer 270 is formed about a thickness, corresponding to a step height, more thickly than the protection layer 270 formed on a non-isolation area. Thus, at least a portion 270a of the protection layer 270 can remain even after a subsequent dual exposure process, thereby preventing the gate connecting lines 223a from being exposed to the outside.

Referring to FIGS. 1 and 12, in step of patterning the pixel electrode 281, a third conductive layer, i.e., a transparent conductive layer formed in the pad area 120 of the substrate 210 is patterned to form a gate auxiliary pad 282 connected to the gate pad 222a through the second contact hole 272. That is to say, after forming a photoresist layer on the protection layer 270, a photoresist layer pattern is formed by performing a photolithography processes including an exposure process and a developing process, the protection layer 270 is etched using the photoresist layer pattern as an etch mask to form the second contact hole 272. During the exposure process, an overall area of the substrate 210 may be divided into a plurality of exposure areas A1 and A2 to carry out divisional exposure. In step of forming of the gate auxiliary pad 282, the data auxiliary pad connected to the data pad 263 is also formed. The gate auxiliary pad 282 and the data auxiliary pad may be omitted, if necessary. In such a case, the gate pad 222a and the data pad 263 are liable to exposure.

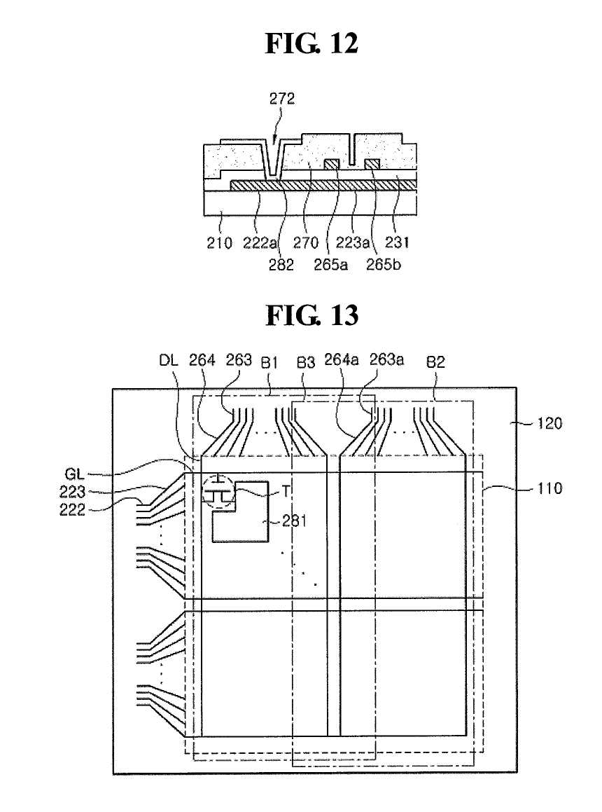

While it has been illustrated in the manufacturing method of the thin film transistor substrate according to the first embodiment by way of example that the plurality of exposure areas A1 and A2 are divided in substantially the same direction with a direction in which the gate line GL is formed, and dual exposure is carried out in an area where some gate connecting lines 223a are formed, the invention is not limited to the illustrated example, the plurality of exposure areas (B1 and B2 of FIG. 13) may be divided in substantially the same direction with a direction in which the data line DL is formed, and dual exposure may be carried out in an area where some data connecting lines (264a of FIG. 13) are formed. Hereinafter, a method for manufacturing the thin film transistor substrate according to a second embodiment. Here, the same explanations as above will not or briefly be given.

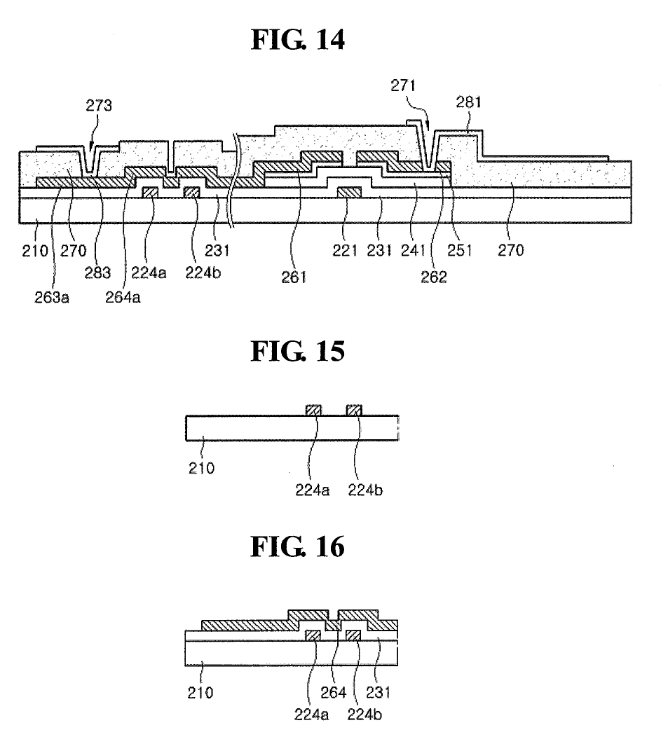

FIG. 13 is a plan view of a thin film transistor substrate according to a second embodiment of the present invention, and FIG. 14 is a sectional view of the thin film transistor substrate shown in FIG. 13.

Referring to FIGS. 13 and 14, the plurality of exposure areas B1 and B2 are divided in substantially the same direction with a direction in which the data line DL is formed. In order to ensure a predetermined exposure margin, the plurality of exposure areas B1 and B2 may be configured to overlap each other at their boundaries by a predetermined portion B3. According to the current embodiment of the present invention, the exposure margin is set to be in a range of about 1 to about 2 μm, for example. The thin film transistor substrate includes a transparent insulating substrate 210, a gate line GL extending on the substrate 210 in one direction, and a data line DL extending on the substrate 210 in a direction perpendicular to the gate line GL.

The gate line GL and the data line DL extend outside with respect to a display area 110, and are electrically connected to a gate pad 222 and a data pad 263 in a pad area 120 through a gate connecting line 223 and a data connecting line 264, respectively. The data connecting line 264 is plurally formed and made of the same material with the gate line GL, including one or more data connecting lines 264a having centrally isolated, spaced apart stepped structures 224a and 2224b formed on bottoms thereof. The stepped structures 224a and 2224b make the data connecting lines 264a formed thereon to have secondary stepped structures, that is, structures that are centrally recessed and project at sides. The central recess of each of the secondary stepped structures 224a and 224b is much thinner than a layer to be formed thereon in a subsequent step, i.e., a protection layer 270. Thus, if the protection layer 270 is formed sufficiently thickly on the secondary stepped structures 224a and 2224b, the protection layer 270 formed on the recess, as the result of planarizing of the stepped structures 265a and 265b, may be formed about a thickness, corresponding to a thickness of the protection layer 270, more thickly than the protection layer 270 formed on the projection. Here, the more thickly formed protection layer 270 in a pertinent area is not completely removed even after a subsequent dual exposure process in the course of patterning the protection layer 270, thereby preventing the data connecting lines 264a from being exposed to the outside even if no layer is formed in a subsequent step in the pertinent area. As a result, it is possible to prevent the data connecting lines 264a from corroding due to exposure.

A method for manufacturing the aforementioned thin film transistor substrate according to the second embodiment of the present invention will now be described. In the current embodiment, a display area 110 is formed in substantially the same manner as in the first embodiment, and the following description will be chiefly made with regard to a pad area 120.

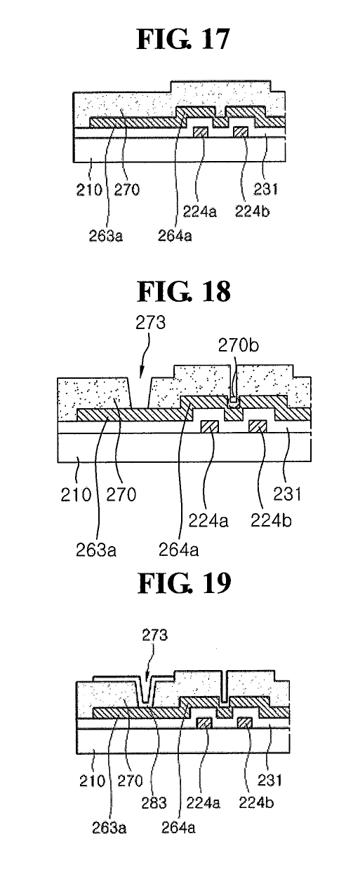

FIGS. 15 through 19 are sectional views illustrating a portion of a pad area for explaining a method for manufacturing the thin film transistor substrate shown in FIG. 13, which correspond to FIGS. 3 through 7, respectively.

Referring to FIG. 15 together with FIG. 13, in step of forming the gate line GL, a gate pad 222 and a gate connecting line 223 are formed in a pad area 120 of a substrate 210 using a first conductive film. Thus, the gate line GL formed in a display area 110 of the substrate 210 is connected to the gate pad 222 through the gate connecting line 223 to receive gate signals through the gate pad 222. Meanwhile, centrally isolated, spaced apart stepped structures 224a and 224b are formed on an area where data connecting lines 264a existing in a dual exposure area when patterning of the protection layer 270 using a portion of the first conductive film. Here, an isolation area of the stepped structures 224a and 224b may be formed by removing partially or completely the first conductive film. In addition, the isolation area of the stepped structures 224a and 224b is preferably equal to or greater than a width of the dual exposure area B3 during patterning of the protection layer 270.

Referring to FIG. 16 together with FIG. 13, in step of forming the data line DL, the data pad 263 and the data connecting line 264 are formed in a pad area 120 of the substrate 210 using the second conductive film. Thus, the data line DL formed in the display area 110 of the substrate 210 is connected to a data pad 263 through the gate connecting line 263 to receive data signals through the data connecting line 264. Here, the data connecting lines 264 existing in the dual exposure area B3 during patterning of the protection layer 270 are formed on bottoms of the stepped structures 224a and 224b have secondary stepped structures, that is, structures that are centrally recessed and project at sides.

Referring to FIG. 17 together with FIG. 13, in step of forming the protection layer 270, the protection layer 270 is formed in the entire pad area B2 including the secondary stepped structures. Here, the protection layer 270 preferably has a thickness much greater than a width of a recess of each of the secondary stepped structures. Accordingly, the protection layer 270 formed on the recess, as a result of planarizing the secondary stepped structures, is formed more thickly than the protection layer 270 formed on the projection by a step height which corresponds to a top surface height difference between of the projection and the recess.

Referring to FIG. 18 together with FIG. 13, in step of patterning the protection layer 270, the protection layer 270 formed in the pad area 120 of the substrate 210 is patterned to form a third contact hole 273 exposing a data pad 263a. That is to say, after forming a photoresist layer on the protection layer 270, a photoresist layer pattern is formed by performing a photolithography processes including an exposure process and a developing process, the protection layer 270 is etched using the photoresist layer pattern as an etch mask to form the third contact hole 273. During the exposure process, the overall area of a substrate 1110 may be divided into a plurality of exposure areas B1 and B2 to carry out divisional exposure. Here, in order to ensure a predetermined exposure margin, the plurality of exposure areas B1 and B2 are preferably configured to overlap each other at their boundaries by a predetermined portion B3, for example, in a range of about 1 to about 1 μm. Accordingly, in the general etching process, since the protection layer 270 is excessively removed through dual exposure, some gate connecting lines 264a existing in a pertinent area may be exposed. However, during the etching process according to this embodiment, the data connecting lines 264 existing in the dual exposure area B3 are formed as secondary stepped structures that are centrally recessed and project at sides. Accordingly, the protection layer 270 is formed on the recess corresponding to the dual exposure area B3 more thickly by a thickness difference between the projection and the recess. Thus, at least a portion 270b of the protection layer 270 can remain even after a subsequent dual exposure process, thereby preventing the data connecting lines 264a from being exposed to the outside.

Referring to FIG. 19 together with FIG. 13, in step of patterning the pixel electrode 281, a third conductive layer, that is, a transparent conductive layer, formed in the pad area 120 of the substrate 210 is patterned to form an auxiliary data pad 283 connected to the data pad 263a through the third contact hole 273. Although not shown, in the same step of forming the auxiliary data pad 283, an auxiliary gate pad connected to the gate pad 222 is also formed. If necessary, the auxiliary data pad 283 and the auxiliary gate pad 283 may be omitted. In such a case, the data pad 263a and the gate pad 222 may be exposed to the outside.

Meanwhile, although not shown, separately from the thin film transistor substrates according to the first and second embodiments, a color filter substrate can be manufactured. The color filter substrate is a transparent substrate having a common electrode formed on its front surface, and including a black matrix for preventing light leakage among various pixel areas, an R, G and B color filter formed in a lattice for realizing various colors into the respective pixel areas, and a column spacer having a predetermined height to maintain a cell gap in a given area. In order to improve interface adherence and a flatness property, an over coat layer may further be formed between the color filter and the common electrode. Next, two substrates are attached such that the pixel electrode of the thin film transistor substrate, and the common electrode of the color filter substrate face each other and a liquid crystal layer is disposed therebetween to form a liquid crystal panel. Here, a predetermined sealing member may be provided along the periphery of at least one substrate to hermetically seal the liquid crystal layer and attach the two substrates to each other.

While only a structure in which a gate electrode is positioned below a source electrode and a drain electrode, i.e., a bottom-gate thin film transistor, has been illustrated in the figures of the first and second embodiments, the present invention may also be applied to the other type thin film transistor in which a gate electrode is positioned above a source electrode and a drain electrode, i.e., a top-gate thin film transistor.

According to the present invention, in a structure in which lines formed on a substrate covered by a protection layer, centrally isolated, spaced apart stepped structures are formed over or below some of the lines, and a protection layer is formed on the lines such that the protection layer is formed about a thickness corresponding to a step height more thickly than a non-isolation area on the isolation area of the stepped structures. Thus, a portion of the protection layer can remain even after a subsequent dual exposure process, thereby preventing wiring corrosion due to wiring exposure.

In addition, according to the present invention, since stepped structures for preventing wiring exposure can be formed over or below some of lines using the conventional mask process for forming gate lines or data lines, an increase in the manufacturing cost due to additional mask processes can be avoided.

Further, since wiring exposure can be prevented, wiring corrosion over time is not generated. Accordingly, causes of malfunction, including short-circuit or open-circuit due to wiring corrosion occurring after extended period of time, are eliminated In addition, according to the present invention, since stepped structures for preventing wiring exposure can be formed over or below some of lines using the conventional mask process for forming gate lines or data lines, an increase in the manufacturing cost due to additional mask processes can be avoided.

Further, since wiring exposure can be prevented, wiring corrosion over time is not generated. Accordingly, causes of malfunction, including short-circuit or open-circuit due to wiring corrosion occurring after extended period of time, are eliminated, thereby providing a high initial operation reliability even after prolonged use.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A thin film transistor substrate comprising:
a substrate having a display area and a pad area defined in the vicinity of the display area;
a signal line formed in the display area and a signal pad formed in the pad area; and
at least one connecting line which connects the signal line and the signal pad and includes a first line and a second line disposed on the first line;
wherein at least one of the first line and the second line has centrally isolated, spaced apart stepped structures.

2. The thin film transistor substrate of claim 1, wherein the signal line includes a gate line and a data line.

3. The thin film transistor substrate of claim 2, wherein the first line is made of the same material as the gate line, and the second line is made of the same material as the data line.

4. The thin film transistor substrate of claim 1, further comprising a protection layer formed over the signal line and the signal pad.

5. The thin film transistor substrate of claim 4, wherein the protection layer includes at least one contact hole, and the centrally isolated, spaced apart stepped structures corresponds to a dual exposure area during an exposure process for forming the contact hole.

6. The thin film transistor substrate of claim 5, wherein a distance between the stepped structures is greater than or equal to a width of the dual exposure area.

7. The thin film transistor substrate of claim 1, wherein the distance between the stepped structures is in a range of about 1 to 5 μm, and a step height is in a range of about 0.5 to 1.0 μm.

8. A method for manufacturing the thin film transistor substrate comprising:
providing a substrate;
forming a first conductive film on the substrate, and patterning the first conductive film to form a gate line, a gate pad and a gate connecting line which connects the gate line and the gate pad;
forming an insulating layer on the overall structure which includes the gate line, the gate pad and the gate connecting line; and
forming a second conductive film on the overall structure which includes the gate line, the gate pad and the gate connecting line, and patterning the second conductive film to form a data line, a data pad and a data connecting line which connects the data line and the data pad,
wherein the patterning of the second conductive film comprises forming centrally isolated, spaced apart stepped structures on a portion of the gate connecting line using a portion of the second conductive film.

9. The method of claim 8, after the patterning of the second conductive film, further comprising:
forming a protection layer on the data pattern; and
partially removing the protection layer to form a contact hole.

10. The method of claim 9, wherein the forming of the contact hole comprises:
forming a photoresist layer on the protection layer by carrying out divisional exposure on the photoresist layer to form a photoresist layer pattern; and
etching the protection layer using the photoresist layer pattern as an etch mask.

11. The method of claim 10, wherein the divisional exposure is carried out by partially overlapping the exposure area in a state in which the exposure area subjected to dual exposure due to overlapping is equal to or smaller than a distance between the stepped structures.

12. The method of claim 11, wherein an overlapping margin of the divisional exposure is in a range of about 1 to 2 μm.

13. The method of claim 10, wherein the distance between the stepped structures is in a range of about 1 to 5 μm, and a step height is in a range of about 0.5 to 1.0 μm.

14. A method for manufacturing the thin film transistor substrate comprising:
providing a substrate;
forming a first conductive film on the substrate, and patterning the first conductive film to form a gate line, a gate pad and a gate connecting line which connects the gate line and the gate pad;
forming an insulating layer on the overall structure which includes the gate line, the gate pad and the gate connecting line; and
forming a second conductive film on the overall structure including the gate line, the gate pad and the gate connecting line, and patterning the second conductive film to form a data line, a data pad and a data connecting line which connects the data line and the data pad,
wherein the patterning of the first conductive film comprises forming centrally isolated, spaced apart stepped structures on a portion of the data connecting line using a portion of the first conductive film.

15. The method of claim 14, after the patterning of the second conductive film, further comprising:
forming a protection layer on the data pattern; and
partially removing the protection layer to form a contact hole.

16. The method of claim 14, wherein the forming of the contact hole comprises:
forming a photoresist layer on the protection layer by carrying out divisional exposure on the photoresist layer to form a photoresist layer pattern; and
etching the protection layer using the photoresist layer pattern as an etch mask.

17. The method of claim 16, wherein the divisional exposure is carried out by partially overlapping the exposure area in a state in which the exposure area subjected to dual exposure due to overlapping is equal to or smaller than the distance between the stepped structures.

18. The method of claim 17, wherein an overlapping margin of the divisional exposure is in a range of about 1 to 2 μm.

19. The method of claim 14, wherein the distance between the stepped structures is in a range of about 1 to 5 μm, and a step height is in a range of about 0.5 to 1.0 μm.
